(19) United States
(12) Patent Application Publication
(10) Pub. No.: US 2015/0163860 A1
(43) Pub. Date: Jun. 11, 2015

(54) APPARATUS AND METHOD FOR UNIFORM IRRADIATION USING SECONDARY IRRADIANT ENERGY FROM A SINGLE LIGHT SOURCE

(71) Applicant: Lam Research Corporation, Fremont, CA (US)

(72) Inventors: Vincent E. Burkhart, Cupertino, CA (US); Yorkman Ma, San Jose, CA (US); Martin E. Freeborn, San Jose, CA (US); Ishtak Karim, San Jose, CA (US)

(21) Appl. No.: 14/098,860

(22) Filed: Dec. 6, 2013

(51) Int. Cl. H05B 3/00; H01L 21/324; G02B 19/00; H01L 21/683

(52) U.S. Cl. CPC H05B 3/0047; H01L 21/683; H01L 21/324; G02B 19/0023; G02B 19/009

(57) ABSTRACT

A technique and apparatus are provided for supplying substantially uniform radiant heat energy to a semiconductor wafer in a load lock or process chamber using a light source and a set of radially-symmetric reflectors.

### BACKGROUND

In semiconductor fabrication systems, semiconductor wafers are processed under various environmental conditions. One of those conditions is the semiconductor wafer temperature, which may be adjusted in-situ in a process chamber or which may be set prior to introduction into a process chamber, e.g., a preheat in a loadlock. Semiconductor wafer temperature may be controlled, for example, using a heated pedestal/wafer support and/or using some form of radiant energy, e.g., a heating lamp.

### SUMMARY

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale unless specifically indicated as being scaled drawings.

In some implementations, an apparatus for use with semiconductor processing equipment may be provided. The apparatus may include an outer reflector having a reflective interior surface, a first base aperture, and a second base aperture. The at least one outer reflector may be radially symmetric about a center axis and the second base aperture may be larger than the first base aperture. The apparatus may also include at least one inner reflector having a reflective exterior surface, a first base perimeter, and a second base perimeter. The at least one inner reflector may be radially symmetric about the center axis, the second base perimeter may be larger than the first base perimeter, the at least one inner reflector may be located between the first base aperture and the second base aperture, and the second base perimeter may be closer to the second base aperture than the first base aperture. The at least one inner reflector may prevent substantially all light travelling parallel to the center axis and within a cylindrical volume bounded by a largest second base perimeter of the at least one second base perimeter from reaching the second base aperture without first reflecting at least once off of at least one of the interior surface and the at least one exterior surface when the light originates from a location substantially centered on the center axis and located such that the at least one inner reflector may be interposed between the second base aperture and the location.

In some such implementations, the outer reflector may be a conical frustum reflector, and the at least one inner reflector may be a conical frustum reflector.

In some other or additional implementations, the at least one inner reflector may include at least two inner reflectors spaced apart along the center axis such that the inner reflectors do not overlap along the center axis.

In some other or additional implementations, the at least one inner reflector may include at least two inner reflectors spaced apart along the center axis such that the inner reflectors overlap along the center axis.

In some other or additional implementations, a first line defined by the intersection of a reference plane that is coincident with the center axis and the interior surface may make a first acute angle with respect to the center axis, at least one second line defined by the intersection of the reference plane with the at least one exterior surface may make at least one second acute angle with respect to the center axis, and the first acute angle may be less than the at least one second acute angle. In some such implementations, the first acute angle may be 15°±10°. In some other or additional implementations, at least one of the at least one second acute angle may be 45°±40°.

In some additional implementations, the at least one inner reflector may include at least two inner reflectors, and the second acute angles may be the same. In some other additional implementations, the at least one inner reflector may include at least two inner reflectors, and the at least two second acute angles may increase in value as a function of the respective inner reflector's distance from the first base aperture. In some other additional implementations, the at least one inner reflector may include at least two inner reflectors, and the at least two second base perimeters may increase in size perpendicular to the center axis as a function of the respective inner reflector's distance from the first base aperture. In some alternative additional implementations, the at least one inner reflector may include at least two inner reflectors, and the at least two second base perimeters may decrease in size as a function of the respective inner reflector's distance from the first base aperture.

In some implementations of the apparatus, the apparatus may further include a light source substantially centered on the center axis and positioned such that light is directed towards the second base aperture and onto the at least one inner reflector. In some such implementations, the light source may include at least one infrared heating lamp.

In some implementations of the apparatus, the apparatus may further include a transparent window. The transparent window may be sized such that light from the light source passes through the transparent window and illuminates at least a circular area. The circular area may be located on a wafer reference plane that may be substantially perpendicular to the center axis, and the wafer reference plane may be offset from the second base aperture and the transparent window may be interposed between the reference plane and the second base aperture. The circular area may be centered on the center axis, and the circular area may be at least as large as a nominal semiconductor wafer size that the apparatus is sized to process.

In some implementations of the apparatus, the apparatus may illuminate at least a circular area in a substantially uniform manner when the apparatus is interfaced with a light source that is substantially centered on the center axis and that at least directs light towards the at least one inner reflector and the second base aperture, and the circular area may be located on a wafer reference plane that is substantially perpendicular to the center axis and offset from the second base aperture in a direction away from the at least one inner reflector. In some such implementations, the circular area may have a diameter of approximately 300 mm or approximately 450 mm. In some such implementations, the substantially uniform manner may correlate with an illumination intensity in one or more wavelengths selected from the range of wavelengths from 700 nm to 1 mm that causes a semiconductor wafer located on the wafer reference plane and within the circular area to experience edge-to-center heating that has a uniformity of ±5° C.

In some implementations of the apparatus, the apparatus may further include a semiconductor wafer loadlock with a transparent window and a wafer support surface. The wafer support surface may be inside the loadlock. The outer reflector and the at least one inner reflector may be positioned such that the wafer support surface is substantially perpendicular to the center axis and the second base aperture is closer to the wafer support surface than the first base aperture. The transparent window may be interposed between the at least one inner reflector and the wafer support surface. In some such implementations, the wafer support surface may be provided by a heated wafer support, and the heated wafer support may have an internal heater configured to heat the heated wafer support from within.

In some implementations, an apparatus may be provided that includes an outer reflector having a reflective, substantially conical interior surface; at least one inner reflector having a reflective, substantially conical exterior surface; and a transparent window spanning across a base of the outer reflector. The substantially conical interior surface and the at least one substantially conical exterior surface may taper in the same direction, the at least one inner reflector may be located within a volume bounded by the substantially conical interior surface, the at least one conical exterior surface and the at least one conical interior surface may have cone axes that are substantially coaxial with one another, and the at least one conical exterior surface may prevent substantially all light travelling parallel to the cone axes and within a cylindrical volume bounded by an outermost perimeter of the at least one conical exterior surface from reaching the transparent window without first reflecting at least once off of at least one of the conical interior surface and the at least one conical exterior surface when the light originates from a location substantially centered on the cone axes and located such that the at least one inner reflector is interposed between the transparent window and the location.

In some implementations, an apparatus may be provided that includes an outer reflector having a reflective, substantially conical interior surface, and at least one inner reflector having a reflective, substantially conical exterior surface having a smaller base aperture and a larger base aperture. The substantially conical interior surface and the at least one substantially conical exterior surface may taper in the same direction, the at least one inner reflector may be located within a volume bounded by the substantially conical interior surface, the at least one conical exterior surface and the at least one conical interior surface may have cone axes that are substantially coaxial with one another, and the at least one conical exterior surface and the conical interior surface may be configured to cause light emitted from a light source, when the light source is centered on the cone axes and offset along the cone axes from the at least one conical interior surface such that the light source is further from the larger base aperture than from the smaller base aperture, to be reflected such that light from the light source that emanates closer to the cone axes may be substantially distributed across an annular region on a plane offset from the larger base aperture in a direction away from the light source and such that light from the light source that emanates further from the cone axes is substantially distributed across a circular region on the plane and within or overlapping with the annular region.

These and other aspects of this disclosure are explained in more detail with reference to the accompanying Figures listed below.

### BRIEF DESCRIPTION OF THE DRAWINGS

FIG. 1A depicts an isometric section view of an example of an apparatus having a heater assembly and a loadlock.

FIG. 1B depicts a removed section view of the example apparatus from FIG. 1.

FIG. 2A depicts an isometric section view of an alternate example apparatus featuring nested inner reflectors.

FIG. 2B depicts a removed section view of the apparatus 200.

FIG. 3A depicts an isometric section view of another alternate example apparatus featuring spaced-apart inner reflectors.

FIG. 3B depicts a removed section view of the apparatus 300.

FIG. 4 depicts a plot comparing temperature distribution across an example semiconductor wafer for heating performed with an apparatus having a reflector assembly as described herein and an apparatus having no reflector assembly as described herein.

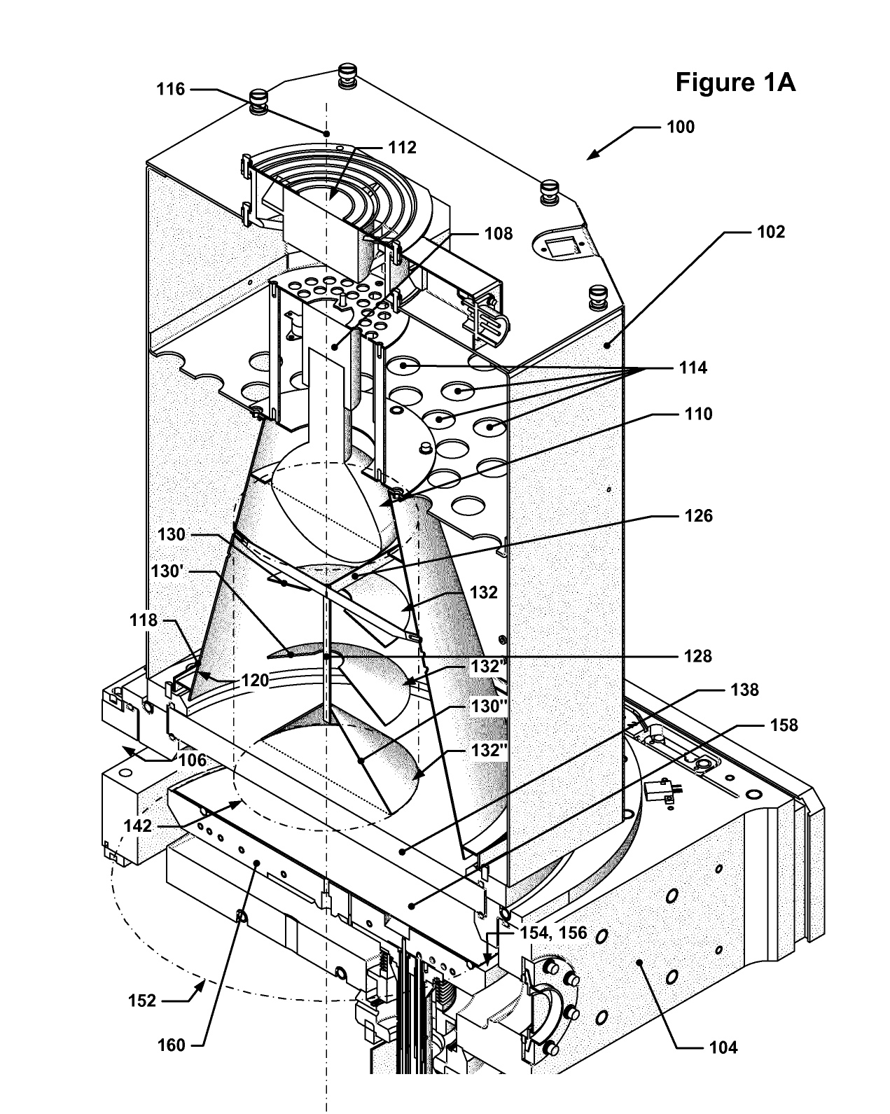

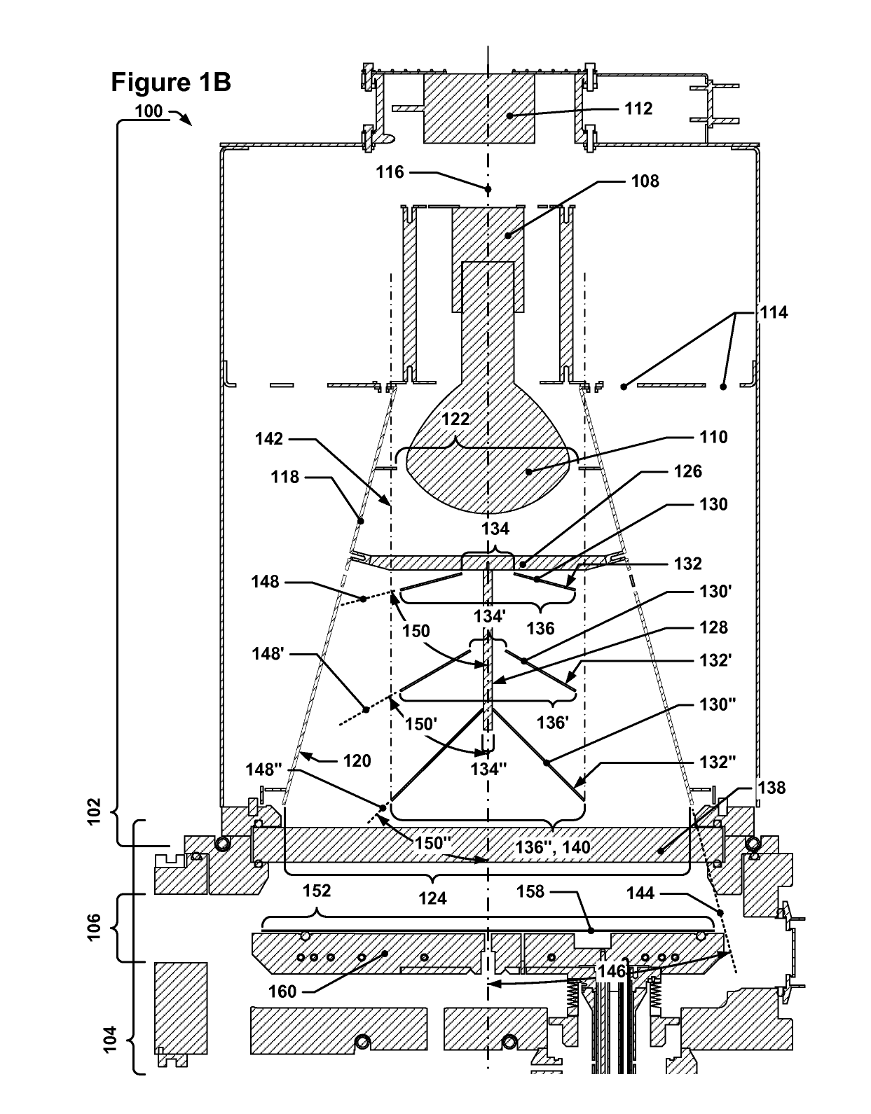

FIGS. 1A through 3B are drawn to scale within each Figure, although not necessarily from Figure to Figure.

### DETAILED DESCRIPTION

Examples of various implementations are illustrated in the accompanying drawings and described further below. It will be understood that the discussion herein is not intended to limit the claims to the specific implementations described. On the contrary, it is intended to cover alternatives, modifications, and equivalents as may be included within the spirit and scope of this disclosure as defined by the appended claims. In the following description, numerous specific details are set forth in order to provide a thorough understanding of the present disclosure. The present disclosure may be practiced without some or all of these specific details. In other instances, well-known process operations have not been described in detail in order not to unnecessarily obscure the present disclosure.

Provided herein are various examples of a heater assembly for use with semiconductor load locks or process chambers. Generally speaking, the heater assembly may include a light source (or an interface for mounting a light source), an outer reflector with a reflective interior surface, and one or more inner reflectors, each with a reflective exterior surface. The light source, for example, may be a single lamp or may be provided by a plurality of lamps. The exterior surface and the at least one interior surface may have radial or axial symmetry about a center axis, and the light source may be substantially centered on the center axis. In many implementations, the interior surface and the at least one exterior surface may be conical or have the shape of a conical frustum. The light source (or the light source mounting interface) may be positioned and oriented such that the light source directs light towards the at least one inner reflector. The at least one inner reflector may be located within the outer reflector, and the reflective surfaces provided by the interior surface and the at least one exterior surface may be configured to reflect the light emitted from the light source such that a relatively uniform illumination field is developed across a circular area on a plane offset from the outer reflector and located on the opposite side of the at least one inner reflector from the light source, e.g., across a semiconductor wafer located beneath the heater assembly.

It is to be understood that while the examples discussed herein are discussed in the context of a loadlock with a heater assembly, a similar heater assembly may be used with a variety of other types of chambers used in semiconductor fabrication, e.g., process chambers. Moreover, it is to be appreciated that the reflector assemblies discussed herein may also be used with other light sources and for other purposes than semiconductor fabrication. For example, the reflector assemblies discussed herein may be used with light sources such as infrared lamps or may, in some implementations, be used with light sources that predominantly emit visible light, e.g., white light. The reflector assemblies discussed herein may also be used in applications such as low-power lighting, e.g., as a reflector assembly to spread light from a relatively small point source, e.g., a super-bright LED, over a large, substantially circular area in a substantially uniform manner. Such reflector assemblies may be useful in applications such as theater lighting, household lighting, headlights for planes, cars, or other vehicles, etc.

FIG. 1A depicts an isometric section view of an example of an apparatus 100 having a heater assembly and a loadlock. As shown in FIG. 1A, a heater assembly 102 may be mounted to a loadlock 104 and a transparent window 138 may separate the heater assembly 102 from the loadlock 104. The transparent window 138 may serve as an environmental barrier that allows light from the heater assembly 102 to pass into the loadlock environment (or chamber environment) while keeping such environment isolated from the heater assembly 102. The loadlock 102 may include a wafer load/unload port 106 and a wafer support 160 that may be used to support a semiconductor wafer 158 within the loadlock 102 on a wafer support surface 156. The wafer support surface 156 may also define a wafer reference plane 154. It is to be understood that reference to a “semiconductor wafer” herein may refer to wafers that are not made of a semiconductor material but that are used in semiconductor manufacturing processes as a substrate for supporting semiconductor materials that are deposited on the wafer, e.g., an epoxy wafer. Thus, the term “semiconductor wafer” may refer to both wafers made of a semiconductor material, e.g., silicon, and to wafers that are made of a non-semiconductor material, e.g., epoxy.

The heater assembly 102 may have a light source 110 that is supported by a light source interface 108, e.g., an electrical socket configured to support the light source 110 and provide electrical power to the light source 110. The light source 110 may be substantially centered along a center axis 116 of the heater assembly 102 (there may be some minor misalignment, for example, due to imperfections in the light source 110's construction and due to slop in the light source interface 108/light source 110 connection). A fan 112 may be included in the heater assembly 102 in order to draw hot air that is produced through the illumination of the light source 110 out of the heater assembly 102. Ventilation holes 114 may be provided within the heater assembly 102 in order to facilitate air flow towards the fan 112.

As can be seen, an outer reflector 118 may be provided that has a radially- or axially-symmetric interior surface 120 that may be centered on the center axis 116, e.g., with its axial or radial symmetry axis coaxial with the center axis 116. The interior surface 120 may be a reflective surface, e.g., nickel-plated or otherwise made reflective. While in the depicted example the interior surface 120 largely has the shape of a right conical frustum, other types of interior surface 120 may be used, e.g., a right conic shape having a hexadecagonal (16-sided) cross-sectional shape. It is to be understood that reference to axially- or radially-symmetric surfaces, features, etc. within this application refers to surfaces, features, etc. that are substantially axially- or radially-symmetric. Such symmetry may be interrupted by minor variances, e.g., a seam in an outer reflector that is the result of the manufacturing process used to make the outer reflector or fastening features used to connect the outer reflector to other structures may technically result in a loss of theoretical radial or axial symmetry, but one of ordinary skill in the art would recognize and understand that such surfaces, features, etc. are still, for all practical purposes, radially- or axially-symmetric.

In addition to the outer reflector 118, at least one inner reflector 130 may be included in the heater assembly 102. Each at least one inner reflector 130 also may be radially- or axially-symmetric about the center axis 116. The at least one inner reflector 130 may be supported within the outer reflector 118 by a support frame 126. In the event that multiple inner reflectors 130 are used, as is shown in FIG. 1A, a center support rod 128 may be used to provide support to the additional inner reflectors 130, e.g., inner reflectors 130′ and 130″. The inner reflectors 130 also may be supported using structures other than the structures shown. FIG. 1A shows three inner reflectors: inner reflectors 130, 130′, and 130″. Each inner reflector may have a corresponding exterior surface 132, 132′, and 132″ that is reflective. As with the interior surface 120 of the outer reflector 118, the exterior surfaces 132, 132′, and 132″ may, as shown, have the shape of a right conical frustum, although other types of exterior surface 132 may be used, e.g., right conic sections with non-circular cross-sections.

The center support rod 128 may be threaded to allow each inner reflector 130, 130′, and 130″ to be easily positioned along the center axis 116 (the reflectors may be held in place through the use of jam nuts or other threaded interfaces with the threaded rod). Such a structure may allow each inner reflector to be independently positioned with respect to the outer reflector 118, which, in turn, allows the illumination intensity attributable to each inner reflector 130, 130′, and 130″ to be adjusted independently. Each such axial adjustment of one of the inner reflectors 130, 130′, and 130″ may cause a radial shift in illumination intensity; by adjusting each inner reflector, the overall radial illumination intensity may be fine-tuned as needed.

The exterior surfaces 132, 132′, and 132″ and the interior surface 120 may also be provided by non-conic axially- or radially-symmetric surfaces, e.g., surfaces formed by the revolution of a curved profile about the center axis 116. For example, such surfaces may be provided by a profile that is at least partially parabolic and that is rotated about the center axis 116. In another example, the profile may include a number of small, local variations, e.g., be wavy or corrugated, along a larger nominal profile, e.g., a parabola or straight line. This may result, for example, in a surface that is substantially conical but that has a wavy or rippled texture. It is also to be understood that while the example shown features three inner reflectors, a different number of inner reflectors may be used, e.g., one inner reflector, two inner reflectors, or more than three inner reflectors. Generally speaking, the greater the number of inner reflectors used, the more uniform the illumination may become, although this is subject to packaging constraints—at some point, the number of inner reflectors may block more light than is reflected. While such implementations may result in greater illumination uniformity, it may take significantly longer to achieve the desired exposure due to the reduced intensity of light that reaches the semiconductor wafer. Another factor is that each additional inner reflector may add to cost and complexity of the heater assembly. Generally speaking, the number of inner reflectors may be increased as needed in order to reach the required level of illumination uniformity mandated by a particular semiconductor manufacturing process.

FIG. 1B depicts a removed section view of the example apparatus from FIG. 1. Further interrelationships between the various elements discussed above are discussed with reference to FIG. 1B.

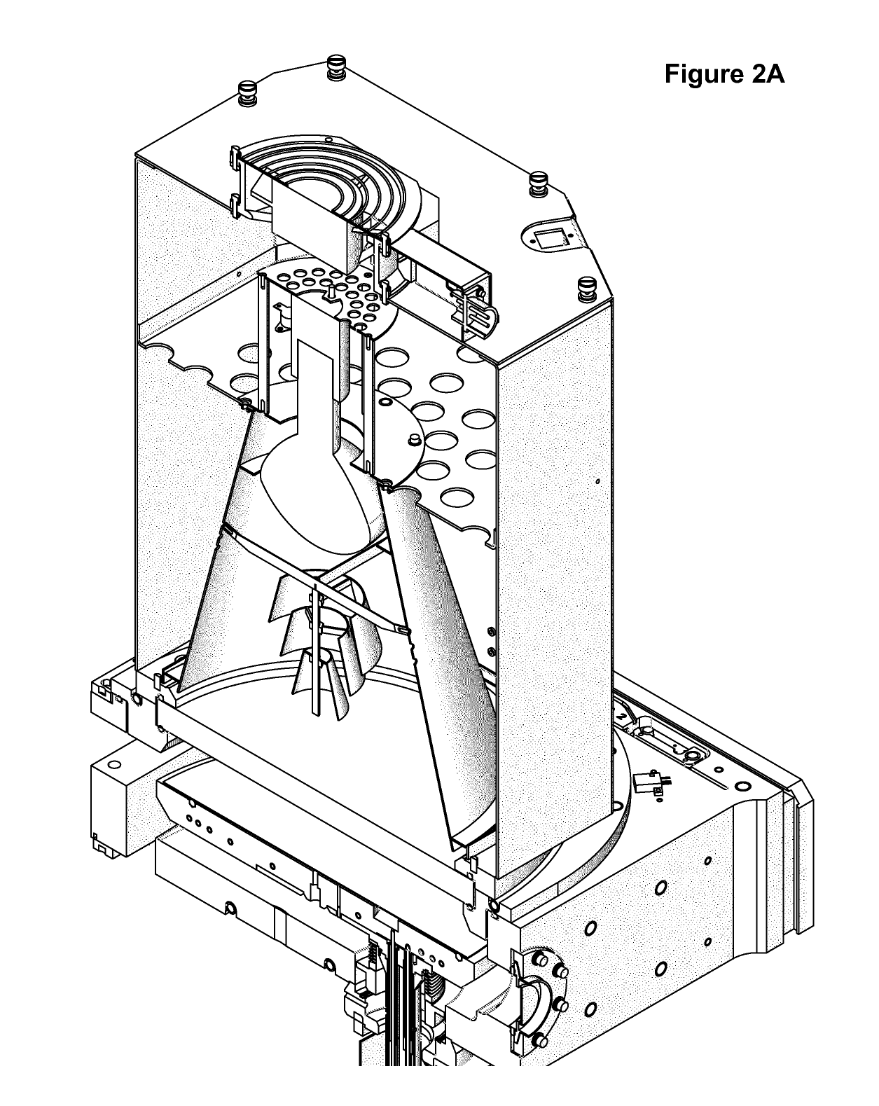

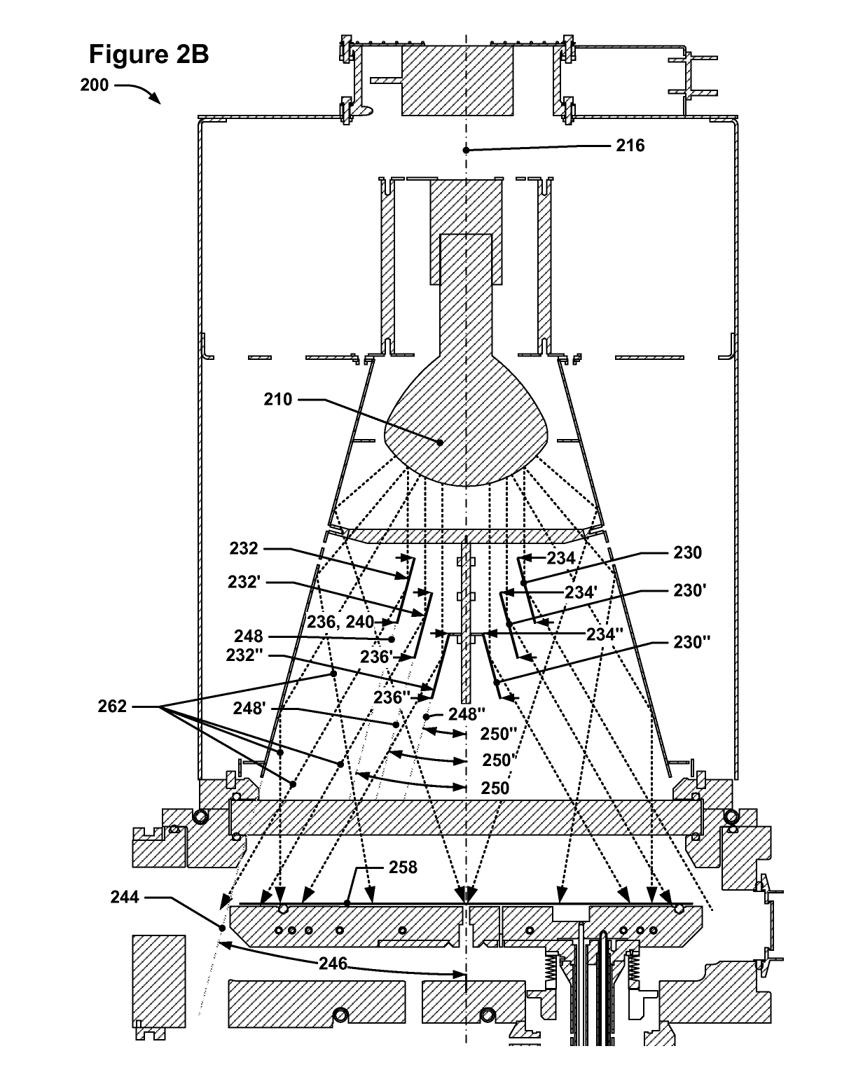

In FIG. 1B, lines defined by the intersection of the interior surface 120 and the at least one exterior surfaces 132, 132′, and 132″ with a sectioning plane passing through the center axis 116 are shown. For example, a first line 144 may be defined by the intersection of the interior surface 120 and such a sectioning plane. The first line 144 may make a first acute angle 146 with respect to the center axis 116. Similarly, at least one second line 148 may be defined by the intersection of the at least one exterior surface 132 and the center axis 116. Each second line 148 may make a second acute angle 150 with respect to the center axis 116. In FIG. 1B, three second lines are indicated, each corresponding to a different inner reflector 130: second line 148, second line 148′, and second line 148″. These second lines each have a corresponding second acute angle: second acute angle 150 (about 75°), second acute angle 150′ (about 60°), and second acute angle 150″ (about 45°). It is to be understood that, in some implementations, the second lines 148, 148′, and/or 148″ may also be perpendicular, or partially perpendicular to the center axis 116 (for example, in FIG. 2B, which is discussed later below, the inner reflector 230″ has an exterior surface 232″ that includes a flat “top,” i.e., an exterior surface that includes a portion that is perpendicular to the center axis 216). Such “perpendicular” portions of exterior surfaces may act as a light shield, although they may result in little, if any, of the light that strikes them reaching the semiconductor wafer.

In some implementations, the second acute angles 150, 150′, and 150″ may be the same as the first acute angle 146. In other implementations, one or more of the second acute angles 150, 150′, and 150″ may be greater than the first acute angle 146. In some implementations, one or more of the second acute angles 150, 150′, and 150″ may be less than the first acute angle 146, although this may have the effect of weakening the light-spreading behavior of the heater assembly.

In addition to the lines and angles defined by various features discussed above, the outer reflector 118 and the inner reflectors 130, 130′, and 130″ may have various other reference dimensions. For example, the outer reflector 118 may have a first base aperture 122 and a second base aperture 124. Similarly, the inner reflectors 130, 130′, and 130″ may have first base perimeters 134, 134′, and 134″, respectively, and second base perimeters 136, 136′, and 136″, respectively. The largest second base aperture, e.g., the second base aperture 136″ in this example, may also be referred to as the outermost perimeter 140 of the inner reflectors 130, 130′, and 130″.

In some implementations, the inner reflector 130 may prevent light travelling from the light source 110 and parallel to the center axis 116 from reaching the second base aperture 124 without first reflecting off of the interior surface 120, at least one exterior surface 132/132′/132″, or both. Accordingly, the interior surface (or the interior surfaces as a whole, when viewed along the center axis 116) may provide an opaque or reflective barrier to light travelling parallel to the center axis 116 within the cylindrical volume 142. For example, in FIGS. 1 and 2, the inner reflectors 130 and 130′ both have holes in the center that allow light travelling parallel to the center axis 116 to pass through the holes. However, the inner reflector 130″ does not have such a hole, so light that passes through the first two inner reflectors 130 and 130′ may be reflected off of the third inner reflector 130″ and towards the interior surface 120 of the outer reflector 118, thus preventing such light from reaching the second base aperture 124 without first reflecting off of the interior surface 120, the exterior surface 132, the exterior surface 132′, and/or the exterior surface 132″.

In some implementations with multiple inner reflectors 130, the inner reflectors 130 may be spaced apart along the center axis 116 such that the first base perimeter 134 or the second base perimeter 136 of each inner reflector 130 is not located between the first base perimeter 134 and the second base perimeter 136 of any adjoining inner reflector 130. In some other implementations with multiple inner reflectors 130, however, the inner reflectors 130 may overlap each other to some extent along the center axis 116 such that the first base perimeter 134 and/or the second base perimeter 136 of each inner reflector 130 is located between the first base perimeter 134 and the second base perimeter 136 of any adjoining inner reflector 130. In some implementations, however, some of the inner reflectors 130 may overlap, as discussed above, and other inner reflectors 130 may be spaced apart, as discussed above.

Generally speaking, the outer reflector 118 and the at least one inner reflector 130 may be oriented such that the first acute angle 146 and the at least one second acute angle 150 are acute with reference to a common ray along the center axis 116. The second acute angle or angles 150 may generally be the same or greater than the at least one first acute angle 146. In some implementations, the first acute angle 146 may be between about 5° and 45°, and the second acute angle or second acute angles may be between about 5° and 90°. In some implementations with multiple inner reflectors 130, the second acute angles 150 may increase in value from inner reflector 130 to inner reflector 130 as the inner reflectors 150 approach the light source 110 or the light source interface 108 (as demonstrated in FIG. 1A). In some implementations, in order to reduce potential heat loss through the interior surface 120, the first acute angle 146 may be equal to or greater than one half of the beam angle of the light source. This may reduce the number of surfaces that some of the light reflects off of, thus reducing the potential for heat loss.

FIG. 2A depicts an isometric section view of an alternate apparatus featuring nested inner reflectors. Aside from the use of different inner reflectors 230 and potentially a different light source, the apparatus 200 shown in FIG. 2A is largely similar to the apparatus 100 shown in FIG. 1A. Accordingly, the reader is referred to corresponding structures in FIG. 1A for descriptions of the various components in FIG. 2A.

The apparatus 200 in FIG. 2A differs from the apparatus 100 in FIG. 1A in that the reflector assembly utilizes different inner reflectors 230, 230′, and 230″ than the inner reflectors 130, 130′, and 130″ shown in FIG. 1A. Specifically, the inner reflectors 230, 230′, and 230″ have exterior surfaces 232, 232′, and 232″ that are all axially-symmetric right conical frustums with different first base perimeters 234, 234′, and 234″ and different second base perimeters 236, 236′, and 236″. Furthermore, whereas the inner reflectors 130, 130′, and 130′ do not overlap one another along the center axis 116, the inner reflectors 230, 230′, and 230″ overlap each other along the center axis 216, as shown.

FIG. 2B depicts a removed section view of the apparatus 200. As can be seen, the first acute angle 246 and the second acute angles 250, 250′, and 250″ are the same in this example implementation, e.g., about 15°. In addition to the structural features of the apparatus 200, dotted lines showing some example light paths 262 for light emitted from the light source 210 are shown. As can be seen, the light paths 262 indicate that light emitted from the light source 210 may be distributed across the entire area in which a wafer 258 may be located. In the apparatus 200, the light source 210 may be a relatively “wide angle” light source, e.g., may emit light in a cone of approximately 90° or more included angle, e.g., 100°. For the purposes of this disclosure, a “wide angle” light source is to be understood to refer to a light source with an included beam angle that is larger than twice the first acute angle, i.e., a beam that would, in theory, directly illuminate the interior surface 220 when emitted along the center axis 216 and with its illumination center point located at the intersection of the first lines 244.

As can be seen from the light paths 262, light from the light source 210 that travels substantially parallel to the center axis 216 may strike the inner reflectors 230, 230′, and 230″ and be reflected towards the outer perimeter of the wafer 258. Due to the intensity distribution of some light sources, the light that is emitted from the light source 210 along paths nearer to the center axis 216 may be of a higher intensity than light that is emitted from the light source 210 along paths further from the center axis 216. As a result of the reflections of the light paths 262 off of the inner reflectors 230, 230′, and 230″, this higher-intensity light is re-distributed across a larger, annular region about the periphery of the wafer 258. By contrast, weaker intensity light emitted from the light source 210 may be reflected off of the outer reflector 218 and may be concentrated within a circular region within the annular region. In this manner, the natural intensity distribution of the light source may be altered such that the normally higher-intensity light emanating from the light source 210 near the center axis 216 is redistributed within an annular region centered on the center axis 216 and the lower-intensity light emanating from the light source 210 further from the center axis 216 is redistributed within a circular region within the annular region (or centered on and partially overlapping with the annular region). In some such implementations, the annular region may have an internal diameter such that the circular region defined by the internal diameter is contained within or is bounded by an outermost perimeter 240 projected onto the wafer 258 along the center axis 216, and the circular region may have a diameter such that the circular region is contained within or bounded by the outermost perimeter 240 projected onto the wafer 258 along the center axis 216.

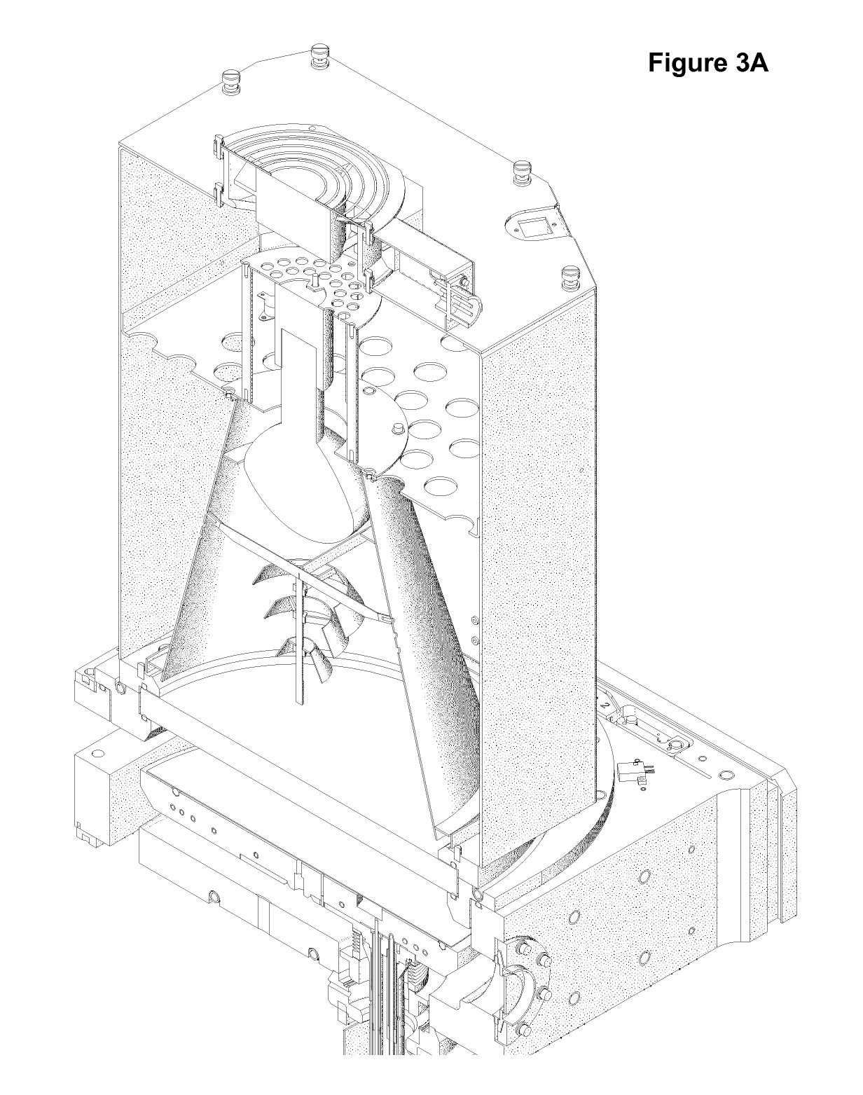

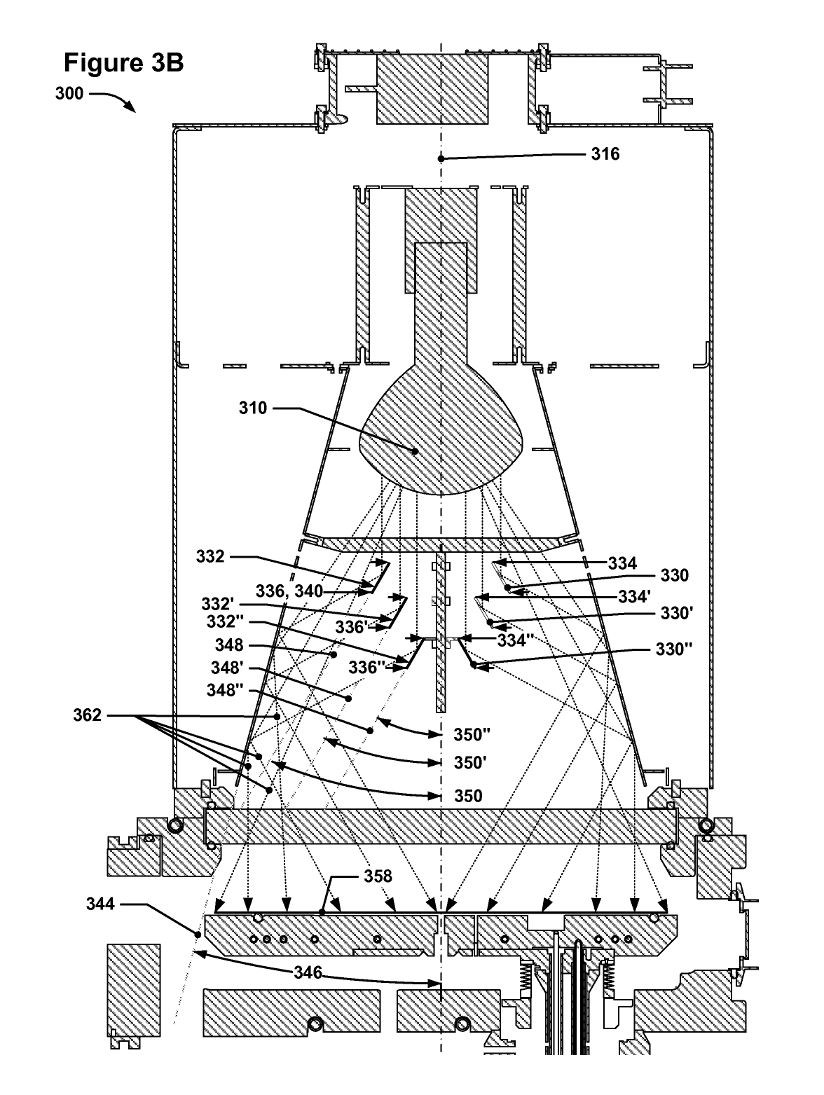

FIG. 3A depicts an isometric section view of another alternate example apparatus featuring spaced-apart inner reflectors.

Aside from the use of different inner reflectors 330 and potentially a different light source, the apparatus 300 shown in FIG. 3A is largely similar to the apparatus 100 shown in FIG. 1A. Accordingly, the reader is referred to corresponding structures in FIG. 1A for descriptions of the various components in FIG. 3A.

The apparatus 300 in FIG. 3A differs from the apparatus 100 in FIG. 1A in that the reflector assembly utilizes different inner reflectors 330, 330′, and 330″ than the inner reflectors 130, 130′, and 130″ shown in FIG. 1A. In this example implementation, the second acute angles 350, 350′, and 350″ are all the same, e.g., about 30°, between the three inner reflectors 330, 330′, and 330″ that are shown, although the first acute angle 346 is of a different value, e.g., about 15°, than the second acute angles 350, 350′, and 350″.

As with the inner reflectors 230, 230′, and 230″, the inner reflectors 330, 330′, and 330″ have exterior surfaces 332, 332′, and 332″ that are all axially-symmetric right conical frustums with different first base perimeters 334, 334′, and 334″ and different second base perimeters 336, 336′, and 336″. In contrast to the inner reflectors 230, 230′, and 230″, the inner reflectors 330, 330′, and 330″ do not overlap each other, as shown.

FIG. 3B depicts a removed section view of the apparatus 300. In addition to the structural features of the apparatus 300, dotted lines showing some example light paths 362 for light emitted from the light source 310 are shown. As can be seen, the light paths 362 indicate that light emitted from the light source 310 may be distributed across the entire area in which a wafer 358 may be located. In the apparatus 300, the light source 310 may be a relatively “narrow angle” light, e.g., may emit light in a cone of approximately 90° or less included angle, e.g., 70°. For the purposes of this disclosure, a “narrow angle” light source is to be understood to refer to a light source with an included beam angle that is less than twice the first acute angle, i.e., a beam that would, in theory, not directly illuminate the interior surface 220 when emitted along the center axis 216 and with its illumination center point located at the intersection of the first lines 244. The heater assembly 102 shown in FIGS. 1A and 1B is an example of a heater assembly that uses a narrow-angle light source, whereas the heater assembly 302 shown in FIGS. 3A and 3B is an example of a heater assembly that uses a narrow-angle light source that has a beam angle near the transition point between a narrow-angle light source and a wide-angle light source.

As can be seen from the light paths 362, light from the light source 310 that travels substantially parallel to the center axis 316 may strike the inner reflectors 330, 330′, and 330″ and be reflected towards the outer reflector 318 before being reflected again towards the wafer 358. In this implementation, the light that is reflected off of the inner reflectors 330, 330′, and 330″ may be directed towards the center region of the wafer 358. Light that is reflected in this manner off of an individual inner reflector 330, 330′, or 330″ may have an intensity gradient on the wafer 358 that increases nearer the center axis 316, which is similar to the behavior of the intensity gradient on the wafer 358 without the inner reflectors 330, 330′, and 330″. However, in the arrangement shown, each inner reflector 330, 330′, or 330″ may reflect light that is associated with a particular relative radial position with respect to the other inner reflectors 330, 330′, or 330″ such that the reflected light strikes the wafer 358 at a different relative radial position with respect to the light from the other inner reflectors 330, 330′, or 330″. For example, light emanated downwards from the light source 310 may strike one of the three inner reflectors 330, 330′, and 330″. Such light that strikes the inner reflector 330 may be thought of as being in an “outermost” relative radial position as compared with such light that strikes the inner reflector 330′, which may be thought of as being in an “intermediate” relative radial position, and with such light that strikes the inner reflector 330″, which may be thought of as being in an “innermost” relative radial position with respect to the outermost and intermediate relative radial positions. However, due to the relative positioning of the inner reflectors 330, 330′, and 330″, the relative radial positioning on the wafer 358 of the light that reflects from each inner reflector 330, 330′, or 330″ and reaches the wafer 358 may be different. For example, the axially-aligned light that reaches the inner reflector 330 may be in the outermost radial position as compared with the axially-aligned light that reaches the inner reflectors 330′ and 330″, but may ultimately be reflected such that the reflected light is mostly in an “innermost” radial position on the wafer 358 as compared with the axially-aligned light that reflects off of the inner reflectors 330′ and 330″. Conversely, the axially-aligned light that reaches the inner reflector 330″ may be in the innermost radial position as compared with the axially-aligned light that reaches the inner reflectors 330 and 330′, but may ultimately be reflected such that the reflected light is mostly in an “outermost” radial position on the wafer 358 as compared with the axially-aligned light that reflects off of the inner reflectors 330 and 330′.

As is evident from the number of common structures in apparatuses 100, 200, and 300, in some implementations, much of the apparatus may be used with various different configurations of inner reflectors. Thus, in some implementations, the apparatus may include, for example, a light source interface and an outer reflector, and may also include mounting features that permit one or more inner reflectors (and/or any support frame, support rods, or other supporting structure) to be mounted within the outer reflector in a manner similar to that discussed above, e.g., centered on the center axis and located within the outer reflector. The mounting features may allow a plurality of different reflector assemblies, each having a different set of one or more inner reflectors (different in at least one of size, second acute angle, first and second base perimeters, etc.) that may be tailored to produce a uniform illumination and/or wafer heating pattern with different types of light sources, e.g., light sources of different emissive angle. In addition to using different geometries of inner reflectors, such implementations may also locate the inner reflectors at different axial spacing along the center axis of the heater assembly. For example, the use of a threaded support rod may allow each inner reflector to be individually positioned along the center axis, thus accommodating a wide variety of different inner reflector types that may require a wide variety of inter-reflector spacing. Such implementations may allow a single heater assembly to be used for a variety of different processes having different uniformity requirements by simply changing out the inner reflectors used within.

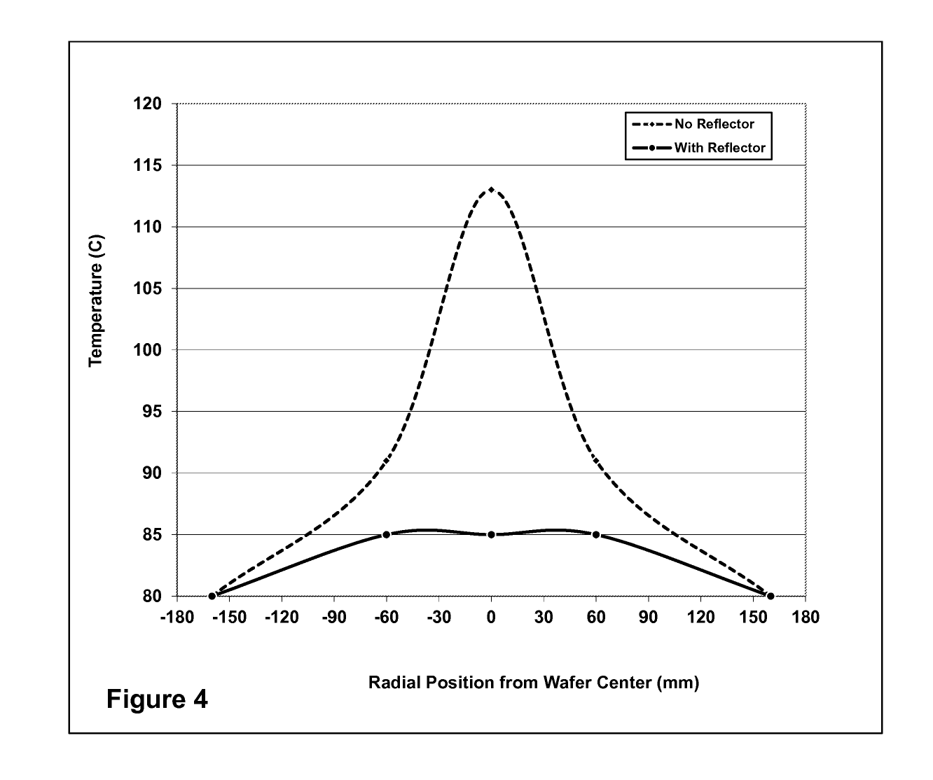

FIG. 4 depicts a plot comparing temperature distribution across an example semiconductor wafer for heating performed with an apparatus having a reflector assembly as described herein and an apparatus without a reflector assembly as described herein (all three of the specific examples shown in FIGS. 1A through 3B exhibit similar behavior). As can be seen, a heater assembly having an outer reflector and at least one inner reflector as described herein may be used to provide a much more even temperature distribution in a wafer that is heated by exposure to the light emitted from the light source. In this case, about a 25° C. temperature gradient arose in a ˜330 mm epoxy semiconductor wafer when exposed to 30 two-second pulses of illumination using a light source and an outer reflector without any inner reflectors. When inner reflectors, e.g., such as those shown in FIGS. 2A and 2B were installed, however, this temperature gradient decreased to approximately 5° C. This is a dramatic improvement in heating uniformity over the test installation without the inner reflector assembly. Generally speaking, the temperature gradient using a heater assembly such as those discussed herein may have a uniformity of ±1° C., ±2° C., ±3° C., ±4° C., ±5° C., or even up to ±10° C. or higher. The present inventors have confirmed via experiment that heater assemblies such as those described herein may achieve ±5° C. or less, e.g., ±4° C., of temperature uniformity across a 330 mm semiconductor wafer.

As discussed above, the heater assembly may be used with a loadlock in order to preheat a semiconductor wafer prior to introduction into a process chamber, transfer chamber, or other chamber. A loadlock is a device that, among other things, allows for a semiconductor wafer to be introduced into a processing environment that is substantially isolated from the ambient environment in order to preserve the processing environment. In many implementations, a loadlock may act as a form of airlock—a semiconductor wafer may be introduced into the loadlock from an ambient environment, e.g., a human-safe, clean room environment, via a first port. A second port may lead from the loadlock into a process chamber, transfer chamber, or other semiconductor processing apparatus chamber. The second port may be closed while the semiconductor wafer is introduced into the loadlock via the first port. After the semiconductor wafer is introduced, the first port may be closed and the environment within the loadlock may be modified, e.g., pumped down to a vacuum condition, supplied with particular gas mixtures, heated, etc., to prepare the semiconductor wafer for introduction into the processing chamber or other chamber. This environmental modification may take some time; during this time, the heater assembly may be used to heat the semiconductor wafer within the loadlock through a transparent window in the loadlock. Such radiant heating may be provided by providing exposure to illumination from the heater assembly light source. Such exposure may be continuous, or may be intermittent, e.g., strobed. In addition to the heater assembly, such an apparatus may also utilize other heat sources to heat up the semiconductor wafer. For example, the wafer support that supports the semiconductor wafer may be in thermal conductive contact with an electrical heater element (or with fluid flow passages through which heated fluid is flowed) that causes the wafer support to also direct heat into the semiconductor wafer for heating purposes.

As discussed earlier, any semiconductor processing chamber (or other chamber, for that matter), may be modified to include a heater assembly and transparent window to allow a semiconductor wafer (or other object) within the chamber at a particular distance from the heater assembly and within the illuminated area of the heater assembly to be evenly heated.

The heater assembly may be made from various materials. For example, aluminum, steel, or other suitable structural materials may be used to provide many of the structural features, e.g., outer housing, support framework, mounting features, etc., of the heater assembly. The inner and outer reflectors may, for example, be made from sheet metal that is stamped or rolled into the desired shape. In some other implementations, the inner and/or outer reflectors may be cast parts that are then machined into shape. The inner and outer reflectors may, for example, be nickel-plated, made from a reflective material, or otherwise coated or covered in a reflective or other material that impacts reflective light behavior (in addition to coatings, surface treatments such as a polish or texturing may also be used in such a manner). In some implementations, the interior surfaces of the inner reflector(s) also may serve as surfaces off of which light may reflect, although such reflections may be relatively low in intensity. In such implementations, the interior surfaces of the inner reflectors may be coated with a non-reflective coating, a reflective coating, or a diffusive coating; such coatings may have different reflective properties than any coatings used (if any) on the exterior surface(s) of the inner reflector(s). The transparent window may, for example, be made from quartz or some other optically transparent material.

The light source discussed above may include one or more individual lamps. In some implementations, a single floodlight, e.g., an R40 flood lamp from General Electric, may be used as the light source. Such a flood lamp may produce a bell-shaped intensity curve when projected onto a plane perpendicular to an axial symmetry axis of the flood lamp, similar to the “No Reflector” curve shown in FIG. 4. In some implementations, the light source may emit light in a specific wavelength range, e.g., in the infrared spectrum of approximately 700 nm to 1 mm. In such implementations, light in other wavelengths may be emitted as well, but may be at a much reduced intensity as compared with the specific wavelength range. In some implementations, the light source may be selected for heating capability, e.g., infrared, but may also or additionally be selected to enhance or provide for degassing operations performed on semiconductor wafers. In some implementations, the light source may be further selected to produce heating temperature ranges from about 65° C. to 120° C., or from about 65° C. to about 300° C., in a semiconductor wafer. In some implementations, the light source may be selected to provide such heating temperature ranges in conjunction with heat supplied from a heater in the wafer support, as discussed above. In some implementations, the light source used may have an inherent directionality, e.g., such as is found in a flood lamp, that causes the light source to primarily emit light as a substantially conical beam.

In some implementations, multiple lamps may be used in a light source. For example, multiple lamps that emit light in different wavelengths may be used in a light source in order to provide emitted light of a particular spectral profile. In another example, multiple, smaller lamps may be used to provide illumination, e.g., such as in an LED light bulb (which often has dozens of small, LED lights that, in aggregate, provide illumination that is equivalent to an incandescent or fluorescent lamp but at a reduced level of power consumption and with less heat energy.

In the semiconductor manufacturing context, the light source used may be tailored to the particular wafer materials used or the process being performed. For example, an infrared light source may be used to heat epoxy-based semiconductor wafers since such epoxy material is susceptible to heating by infrared radiation. By contrast, if semiconductor wafers made of silicon are to be heated, infrared radiation may be largely useless since silicon is largely optically transparent to infrared radiation. In such implementations, it may be more desirable to use a light source that emits visible light with energy that is greater than the band gap of the silicon in order to provide effective heating of the silicon wafer. The apparatus used herein may also be used in semiconductor manufacturing applications where heating is not the primary objective. For example, in some semiconductor operations, a wafer may be exposed to ultraviolet light in order to drive out porogens or in order to cure a material deposited on, or forming part of, the wafer. For example, implementations of the heater assembly discussed herein may be used to provide a UV light source such as may be used in a multi-station UV cure chamber, such as is described in U.S. patent application Ser. No. 11/115,576, filed Apr. 26, 2005, (now issued U.S. Pat. No. 8,137,465) or U.S. patent application Ser. No. 11/688,695, filed Mar. 20, 2007, (now issued U.S. Pat. No. 8,454,750), both of which are hereby incorporated by reference herein in their entireties.

For wide-angle light sources, it may be preferable to configure the inner reflectors such that the lower-intensity light emitted from the light source (at locations relatively distant from the center axis) is redirected towards the center of the wafer being heated. This has the effect of concentrating such light into a smaller area, thus raising the light intensity of that light within that area. At the same time, it may be preferable to configure the inner reflectors such that the higher-intensity light emitted from the light source (at locations relatively close to the center axis) is redirected towards the periphery of the wafer being heated. This has the effect of diffusing such light into a larger area, thus decreasing the light intensity of that light within that larger area.

For narrow-angle light sources, it may also be preferable to configure the inner reflectors such that the lower-intensity light emitted from the light source (at locations relatively distant from the center axis) is redirected towards the center of the wafer being heated. This has the effect of concentrating such light into a smaller area, thus raising the light intensity of that light within that area. At the same time, it may also be preferable to configure the inner reflectors such that the higher-intensity light emitted from the light source (at locations relatively close to the center axis) is redirected towards the periphery of the wafer being heated. This has the effect of diffusing such light into a larger area, thus decreasing the light intensity of that light within that larger area. However, the amount of such intensity redistribution may be greater for narrow-angle light sources than for wide-angle light sources.

For example, the direct illumination intensity profile (illumination without inner/outer reflectors) from a narrow-angle flood lamp, which is usually a bell-curve shape, will be sharper, i.e., have a higher illumination intensity drop-off rate, than from a wide-angle flood lamp. For a given lamp-to-wafer distance, the diameter of beam coverage from a narrow-angle flood lamp will be less than from a wide-angle flood lamp. Furthermore, the direct illumination intensity from a wide-angle flood lamp on the wafer may be relatively more uniform, i.e., subject to lesser intensity drop-offs, than from a narrow-angle flood lamp. Thus, to achieve a similar degree of illumination uniformity, the inner and outer reflectors may need to redistribute the light from a narrow-angle light source to a greater extent than for a wide-angle light source.

Narrow-angle inner reflectors may be used to directly spread the light out from the center to the periphery of the wafer, e.g., without requiring reflection off of the outer reflector. By contrast, wider-angle inner reflectors may reflect such light to the outer reflector instead of directly to the wafer. Such light may be reflected at least twice, e.g., at least once off an inner reflector and at least once off of an outer reflector, before it reaches on the wafer. As a result, the light intensity along the radial direction may be reversed or re-arranged from center to periphery of the wafer, at least with respect to light reaching a particular inner reflector. For example, in some implementations, for light striking a wide-angle inner reflector, the closer the light strikes to the center axis, the further the reflected light may be when it strikes the wafer. Therefore, wide-angle inner reflectors may be particularly suited for use with narrow-beam light sources that require more drastic illumination intensity tuning in order to achieve the desired illumination intensity.

In some implementations, the circular area that bounds the illumination exposure area may correspond with a nominal semiconductor wafer size (or may be sized slightly larger). Nominal semiconductor wafer sizes may, for example, include 100 mm diameter semiconductor wafers, 150 mm diameter semiconductor wafers, 200 mm diameter semiconductor wafers, 300 mm diameter semiconductor wafers (the implementations shown in FIGS. 1A through 3B are for 300 mm wafers), 450 mm diameter semiconductor wafers, and other sizes commonly used in the industry. Equipment used to process semiconductor wafers is typically configured to process a single nominal size of semiconductor wafer, although it may be possible to process semiconductor wafers that are sized smaller than a particular nominal semiconductor wafer size in equipment that is designed to process the particular nominal semiconductor wafer size. In some such cases, multiple smaller semiconductor wafers may be placed within the circular area rather than one larger semiconductor wafer.

The equipment described herein may be connected with various other pieces of equipment, e.g., a loadlock or other chamber, a power supply, a loadlock controller or other system controller, temperature sensors, etc. Chambers or tools that utilize a heater assembly or heater/loadlock assembly as described herein may also include a system controller having instructions for controlling various valves, flow controllers, and other equipment to provide a desired semiconductor process using the heater assembly or assemblies described herein. The instructions may include, for example, instructions to control the light source to provide pre-defined periods of illumination at one or more intensities. The system controller may typically include one or more memory devices and one or more processors configured to execute the instructions such that the apparatus will perform a method in accordance with the present disclosure. Machine-readable media containing instructions for controlling process operations in accordance with the present disclosure may be coupled to the system controller.

In some implementations, a temperature sensor, e.g., a thermocouple in the wafer support or a remote-read temperature sensor capable of non-contact temperature measurement of the wafer, may be connected with a controller that controls the heater assembly and, if one is used, a wafer support heater. The controller may include a memory with instructions for causing the controller to control the supply of power to the light source of the heater assembly (and the wafer support heater, if used) based on the temperatures sensed by the temperature sensor. In this manner, a closed-loop control system may be implemented for providing uniform heating of wafers in the loadlock.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

It will also be understood that unless features in any of the particular described implementations are expressly identified as incompatible with one another or the surrounding context implies that they are mutually exclusive and not readily combinable in a complementary and/or supportive sense, the totality of this disclosure contemplates and envisions that specific features of those complementary implementations can be selectively combined to provide one or more comprehensive, but slightly different, technical solutions. It will therefore be further appreciated that the above description has been given by way of example only and that modifications in detail may be made within the scope of the disclosure.

1. An apparatus for use with semiconductor processing equipment, the apparatus comprising:
an outer reflector having a reflective interior surface, a first base aperture, and a second base aperture, wherein:
the outer reflector is radially symmetric about a center axis, and
the second base aperture is larger than the first base aperture; and
at least one inner reflector having a reflective exterior surface, a first base perimeter, and a second base perimeter, wherein, for each inner reflector:
the at least one inner reflector is radially symmetric about the center axis,
the second base perimeter is larger than the first base perimeter,
the inner reflector is located between the first base aperture and the second base aperture, and
the second base perimeter is closer to the second base aperture than the first base aperture, and wherein:
the at least one inner reflector prevents substantially all light travelling parallel to the center axis and within a cylindrical volume bounded by a largest second base perimeter of the at least one second base perimeter from reaching the second base aperture without first reflecting at least once off of at least one surface selected from the group consisting of: the interior surface and the at least one exterior surface when the light originates from a location substantially centered on the center axis and located such that the at least one inner reflector is interposed between the second base aperture and the location.

2. The apparatus of claim 1, wherein:
the outer reflector is a conical frustum reflector, and
the at least one inner reflector is a conical frustum reflector.

3. The apparatus of claim 1, wherein:
the at least one inner reflector includes at least two inner reflectors spaced apart along the center axis such that the inner reflectors do not overlap along the center axis.

4. The apparatus of claim 1, wherein:
the at least one inner reflector includes at least two inner reflectors spaced apart along the center axis such that the inner reflectors overlap along the center axis.

5. The apparatus of claim 1, wherein:
a first line defined by the intersection of a reference plane that is coincident with the center axis and the interior surface makes a first acute angle with respect to the center axis,
at least one second line defined by the intersection of the reference plane with the at least one exterior surface makes at least one second acute angle with respect to the center axis, and
the first acute angle is less than the at least one second acute angle.

6. The apparatus of claim 5, wherein the first acute angle is 15°±10°.

7. The apparatus of claim 5, wherein at least one of the at least one second acute angle is 45°±40°.

8. The apparatus of claim 5, wherein:
the at least one inner reflector includes at least two inner reflectors, and
the second acute angles are the same.

9. The apparatus of claim 5, wherein:
the at least one inner reflector includes at least two inner reflectors, and
the at least two second acute angles increase in value as a function of the respective inner reflector's distance from the first base aperture.

10. The apparatus of claim 5, wherein:
the at least one inner reflector includes at least two inner reflectors, and
the at least two second base perimeters increase in size as a function of the respective inner reflector's distance from the first base aperture.

11. The apparatus of claim 5, wherein:
the at least one inner reflector includes at least two inner reflectors, and
the at least two second base perimeters decrease in size as a function of the respective inner reflector's distance from the first base aperture.

12. The apparatus of claim 1, further comprising a light source substantially centered on the center axis and positioned such that light is directed towards the second base aperture and onto the at least one inner reflector.

13. The apparatus of claim 12, wherein the light source includes at least one infrared heating lamp.

14. The apparatus of claim 12, further comprising a transparent window, wherein:
the transparent window is sized such that light from the light source passes through the transparent window and illuminates at least a circular area,
the circular area is located on a wafer reference plane that is substantially perpendicular to the center axis,
the wafer reference plane is offset from the second base aperture and the transparent window is interposed between the reference plane and the second base aperture,
the circular area is centered on the center axis, and
the circular area is at least as large as a nominal semiconductor wafer size that the apparatus is sized to process.

15. The apparatus of claim 1, wherein:
the apparatus illuminates at least a circular area in a substantially uniform manner when the apparatus is interfaced with a light source that is substantially centered on the center axis and that at least directs light towards the at least one inner reflector and the second base aperture, and
the circular area is located on a wafer reference plane that is substantially perpendicular to the center axis and offset from the second base aperture in a direction away from the at least one inner reflector.

16. The apparatus of claim 15, wherein:
the circular area has a diameter selected from the group consisting of: approximately 300 mm and approximately 450 mm.

17. The apparatus of claim 15, wherein:
the substantially uniform manner correlates with an illumination intensity in one or more wavelengths selected from the range of wavelengths from 700 nm to 1 mm that causes a semiconductor wafer located on the wafer reference plane and within the circular area to experience edge-to-center heating that has a uniformity of ±5° C.

18. The apparatus of claim 1, further comprising:
a semiconductor wafer loadlock with a wafer support surface inside the loadlock; and
a transparent window, wherein:
the outer reflector and the at least one inner reflector are positioned such that the wafer support surface is substantially perpendicular to the center axis and the second base aperture is closer to the wafer support surface than the first base aperture, and
the transparent window is interposed between the at least one inner reflector and the wafer support surface.

19. The apparatus of claim 18, wherein:
the wafer support surface is provided by a heated wafer support, and
the heated wafer support has an internal heater configured to heat the heated wafer support from within.

20. An apparatus for use with semiconductor processing equipment, the apparatus comprising:
an outer reflector having a reflective, substantially conical interior surface;
at least one inner reflector having a reflective, substantially conical exterior surface; and
a transparent window spanning across a base of the outer reflector, wherein:
the substantially conical interior surface and the at least one substantially conical exterior surface taper in the same direction,
the at least one inner reflector is located within a volume bounded by the substantially conical interior surface,
the at least one conical exterior surface and the substantially conical interior surface have cone axes that are substantially coaxial with one another, and
the at least one substantially conical exterior surface prevents substantially all light travelling parallel to the cone axes and within a cylindrical volume bounded by an outermost perimeter of the at least one conical exterior surface from reaching the transparent window without first reflecting at least once off of at least one surface selected from the group consisting of: the conical interior surface and the at least one conical exterior surface when the light originates from a location substantially centered on the cone axes and located such that the at least one inner reflector is interposed between the transparent window and the location.

21. An apparatus for use with semiconductor processing equipment, the apparatus comprising:
an outer reflector having a reflective, substantially conical interior surface; and
at least one inner reflector having a reflective, substantially conical exterior surface having a smaller base aperture and a larger base aperture, wherein:
the substantially conical interior surface and the at least one substantially conical exterior surface taper in the same direction,
the at least one inner reflector is located within a volume bounded by the substantially conical interior surface,
the at least one substantially conical exterior surface and the substantially conical interior surface have cone axes that are substantially coaxial with one another, and substantially conical exterior surface and the substantially conical interior surface are configured to cause light emitted from a light source, when the light source is centered on the cone axes and offset along the cone axes from the substantially conical interior surface such that the light source is further from the larger base aperture than from the smaller base aperture, to be reflected such that light from the light source that emanates closer to the cone axes is substantially distributed across an annular region on a plane offset from the larger base aperture in a direction away from the light source and such that light from the light source that emanates further from the cone axes is substantially distributed across a circular region on the plane and within or overlapping with the annular region.
